(19) United States
(12) Patent Application Publication
(10) Pub. No.: US 2011/0155218 A1
(43) Pub. Date: Jun. 30, 2011

(54) SOLAR INSTALLATION

(76) Inventors: Arthur Büchel, Ruggell (LI); Franz Baumgartner, Konstanz (DE); Roland Bartholet, Tscherlach (CH)

(21) Appl. No.: 13/054,038

(22) PCT Filed: Jul. 14, 2009
(86) PCT No.: PCT/CH09/00253

§ 371 Date: Mar. 18, 2011

(30) Foreign Application Priority Data
Jul. 14, 2008 (CH) CH 1097/08

(51) Int. Cl. H01L 31/052

(52) U.S. Cl. 136/246

(57) ABSTRACT

The invention relates to a solar installation (11) comprising a plurality of solar panels (19) that are suspended in a row between two supporting cables (15, 16). Anchor points (13, 14), at which both of the supporting cables (15, 16) are directly or indirectly anchored, is provided at least in front of and after the row of solar panels. A spacer (17) is provided at least between each row of solar panels (19) and the anchor points (13, 14), said spacers (17) maintaining the supporting cables (15, 16) at a pre-determined distance in relation to each other in the region of the rows of solar panels (19). At least one of the spacers (17) is mounted on a support (25) so as to be pivotable about a swivel axis (23), and a pivoting device (27) is provided to secure the spacer (17) and the support (25) at a specific pivoting angle in relation to each other. At least one intermediate fastening device is provided.

### CROSS-REFERENCE TO RELATED APPLICATIONS

This application claims priority to PCT Patent Application No. PCT/CH2009/000253 filed on Jul. 14, 2009 and Swiss Patent Application No. 1097/08 filed on Jul. 14, 2008, the entirety of each of which is incorporated by this reference.

### FIELD OF THE INVENTION

The invention relates to solar installations and more specifically to a solar installation having a plurality of solar panels suspended in a row between two supporting cables.

### STATE OF THE ART

Such an installation is known from the prior art in accordance with U.S. Pat. No. 4,832,001, wherein a row of solar panels is suspended between two supporting cables, which are tensioned between two A-frames. The two supporting cables can be pivoted relative to the A-frames about a common pivotable axis, so that the whole row can be tracked about the pivotable axis running in the cable direction depending on the position of the sun.

In one exemplary embodiment, the suspension on the cables is rotatable, so that the solar panels can be aligned to the solar radiation direction about a suspension axis, which runs perpendicularly to the pivotable axis. A tracking cable which is attached to the outer end of a lever parallel to the cables is provided for this purpose. Each panel is equipped with such a lever. The panel is pivoted about the suspension axis by pulling on the lever.

So that the solar panels track the sun, two Freon cans connected to one another are provided for each direction of adjustment. These are only exposed to equal sunshine if they are pointed vertically to the solar radiation direction. If they deviate from this direction one can is heated more than the other, so that Freon flows from this into the other, therefore causing the solar panels to pivot, which aligns the installation to the sun.

In U.S. Pat. No. 4,832,001 also simpler embodiments are illustrated, wherein only the pivotable axis but not the suspension axis is formed. Such an exemplary embodiment is illustrated with a single supporting cable, extending over a plurality of A-frame distances. In each case, a panel array is arranged between two A-frames. Each panel array is equipped with two Freon canisters for aligning the array. The individual panels of an array, which are connected to one another by the one supporting cable and an additional flexible coupling, rotate in unison about the supporting cable. They are equipped with a counterweight, so that the cable is always balanced.

The alignment of the panels only by the Freon canisters and the solar radiation direction has the advantage that the solar panels do not need to be actively tracked to the sun. However, this requires that the panels are already pivoted with minimum force. For this purpose, the solar panels are tensioned between two individual cables. This, however, can lead to the fact that under heavy wind conditions the panels can oscillate, so that the supporting cables begin to swing under their natural frequency. Also, the danger exists that the installation will collapse under wind load and/or snow load.

WO 2008/025001 describes a device with a linear array of solar collectors and solar converters, which are arranged one behind the other on a tensioning structure. The tensioning structure in a simple embodiment consists of two parallel cables mounted at a distance from each other between which the collectors are arranged in a pivotable manner about an individual pivotable axis. A control cable, which can move in the cable direction relative to the tensioning structure, enables the collectors to pivot. The supporting cables are secured to end posts which in turn are anchored to the ground with wire guys. Further posts, which are anchored to the ground by means of wire guys in all directions, are provided between the end posts at regular intervals. The support structure of WO 2008/025001 has the disadvantage that this is very complex and expensive. A further disadvantage is that under heavy wind conditions the cables can begin to swing. In order to avoid this, damping elements, which can be filled with liquid, are arranged on the cables.

U.S. Pat. No. 7,285,719 discloses a support system for solar panels, in which two pairs of pillars are arranged at a distance from each other. Supporting cables, on which a plurality of solar panels is arranged next to one another, are tensioned between the pillars. The pillars of a pair of pillars vary in height, so that the solar panels are arranged at an angle to the horizontal. The pillars are anchored to the ground by cables, which engage on the top of the pillars. If there is a large span between the pillars, a central support may be provided, the strength of which can be less, since this does not have to ensure stability against lateral movements corresponding to U.S. Pat. No. 7,285,719. The support system of U.S. Pat. No. 7,285,719 is disadvantageous in that the solar panels are arranged at a fixed angle to the horizontal and cannot be tracked to the position of the sun. A further disadvantage is that the solar panels are fully exposed to heavy wind conditions. Therefore, there is a danger of collapse in the event of strong cross-winds.

EP-A-0 371 000 discloses a shading device, which consists of a plurality of inclined shading elements parallel to each other which, within the upper region, have solar cells and which, in a similar way to frosted glass, are translucent in the lower region. In accordance with one exemplary embodiment, a cable structure is provided with an upper layer made from tensioned cables crossing over each other and a lower layer of likewise crosswise tensioned cables. The ends of the cables of both layers are secured to an outer beam and between the beams are held up by supports.

EP-A-0 373 234 shows a solar generator with solar cells, which are suspended on cables meshed with one another. Longitudinal stabilization is provided by supporting cables, which are tensioned between supporting pillars. Transverse stabilization is provided by cables, which run from the longitudinal cables to anchorages in the ground. Depending on arrangement of the crosswise running cables, the solar cells are held up by compression or tension.

DE-A-36 43 487 describes an installation for generating electricity made of photovoltaic cells disposed over a wide area. In this case, pillars are connected to one another by a support structure, which consists of supporting cables tensioned in the same way as a suspension bridge. Extension arms which are part of an adjustment device are attached on the side of the pillars. The adjustment device permits the cells to be optimally aligned to the sun. A network with photovoltaic cells is arranged on the extension arms. As a result of the chess-board-like arrangement of the photovoltaic cells, a gap is present between these, through which sunlight can pass unhindered. This has the advantage that the ground under the photovoltaic cells can be used. With the installation of DE-A-36 43 487, it is disadvantageous that the cells can only be adjusted about a single axis. Also, the pillars are not supported against cross-winds.

Even though the solar installations described initially propose different solutions to enable the panels to track the sun according to its position and the season, only little attention is paid to the actual support structure of the solar installation, although this is responsible for quite a substantial part of the production costs.

### SUMMARY OF THE INVENTION

The present invention advantageously provides a cable-based solar installation with a lightweight and, therefore, economic structure, for which only a limited wind load and snow load must be calculated. One advantage of the present invention is to provide an economic and stable support structure, in particular for solar installations, wherein the solar panels are arranged apart between two cables, which can also withstand high wind loads. It is another advantage of the present invention to provide a solar installation, which permits optimum alignment of the solar panels. Yet another advantage of the present invention is to provide, for solar installations, an economic support structure, wherein the solar panels can be pivoted about two axes. A further advantage of the present invention is to provide a solar installation which can also withstand strong winds.

These advantages are achieved according to the invention with a solar installation having intermediate trusses that are formed by pillars with side struts or pillars with guy-wires or a pendulum support (bipod) are inserted, so that they can take up forces at right-angles to the supporting cables and so that the distance between the end stays and the intermediate trusses, that is to say, between two intermediate trusses, is selected so that the cable sag is less than 6%, for example, more than 0.5% and less than 6%, between 0.75% and 5% or between 1% and 3% of the respective distance between the end stays and the intermediate trusses, that is to say, between two intermediate trusses, with the aim of finding an optimum between sag and necessary cable pre-tensioning force. Such intermediate trusses in the following are also called intermediate trusses of the first type. Limitation of the sag has the advantage that the shading by neighbouring solar panels is minimal and that the solar panels can be arranged close together (shading). The solar installation according to the invention has the advantage that the support structure for the panels can be produced economically since, provided a certain amount of cable sag is accepted, the end stays can be less massive. Also, the intermediate trusses of the first type can be more economic than the end stays, since apart from a support function these only need take up forces, which are applied substantially at right angles to the supporting cables, and the weight of the panels. The proposed support structure also has the advantage that no damping elements are necessary as in the case of WO 2008/025001 cited previously. For the solar panels, flat elements may be used.

In accordance with one embodiment of the present invention, the intermediate trusses of the first type can be pivoted about a pivotable axis running substantially perpendicularly to the supporting cables. This has the advantage that the support can participate in expansions of the cable in the longitudinal direction, for example as a result of heavy wind conditions.

The provision of intermediate trusses has the advantage that the design of the supports (for example pillars) can be different. End stays, which can take up very great tensile loads, and intermediate trusses, which can only take up small or no tensile loads in the supporting cable direction, may be provided. The subdivision of the solar installation into unequally long sections by the intermediate trusses has the advantage that natural oscillations cannot build up. It has been shown that there is an unequally long intermediate section per 10 intermediate sections (=section between two supports), per 8 intermediate sections or per 5 intermediate sections. This intermediate section of unequal length can effectively prevent oscillations of the supporting cables from building up.

The distance between the end stays and the intermediate trusses, that is to say, between two intermediate trusses, is more than 15 m, but may be more than 30 m or more than 50 m. Advantageously the distance mentioned is between 50 m and less than 200 m. The fewer the number of intermediate trusses required, generally the lower the production costs. Thus, the distance between the end stays and the intermediate trusses, that is to say, between two intermediate trusses, is between 15 m and 150 m, between 25 m and 80 m, or between 35 m and 70 m. These distances guarantee an optimum between stability and production costs.

In accordance with another embodiment, the intermediate truss of a first type is conceived for stabilizing the supporting cables, in particular with respect to oscillation by heavy wind conditions. Such intermediate trusses or intermediate fastenings can be structurally less massive than the end stays. This first type of intermediate truss can be formed by A-supports in the shape of a bipod or wire guys. The intermediate trusses of the second type are characterized in that they can also take up wind forces in the cable direction. The intermediate truss of a second type additionally includes wire guys or supports in the direction of the supporting cable, in order to take up the wind forces arising on the supporting cable. The use of these intermediate trusses of the second type can alternate at regular or irregular intervals with intermediate trusses of the first type. The intermediate trusses of the second type can be in the form of supports for example, also in the shape of a bipod. An intermediate truss of the second type is advantageously inserted per 3-20 intermediate trusses of the first type, or per 4-12 intermediate trusses of the first type.

In accordance with yet another embodiment, the row of solar panels is subdivided, at least partially, into unequally long sections (A, C) by at least one of the intermediate trusses of the first and/or second type. It has been shown that at least one section per 10 sections should have a different length than the remaining sections.

The intermediate truss of a third type is realized by a support, which support is tensioned by cables or stabilized by struts without the angle of the panels being actively tracked in a coupled manner to the sun. Such a support can be realized by a four-legged frame for example. Such intermediate trusses are conceived for taking up compressive and tensile loads in the supporting cable, but do not need to have any central pillars. A further fourth type of intermediate truss is a stay by means of a cable in the middle of the spacer between the supporting cables, in order to limit wind-induced oscillation of the supporting cables with the panels.

An advantageous solar installation has end stays and intermediate trusses of a first and second type. Such an installation can be economically realized, since various supports, pillars, props or stays are provided for taking up the forces arising.

It consists for example of the following sequence of components:
a) 1 end stay,
b) a certain number, for example, between 2 and 20 or between 3 and 10, of intermediate trusses of the first type,
c) 1 intermediate truss of the second type,
d) a certain number, for example, between 2 and 20 or between 3 and 10, of intermediate trusses of the first type,
e) further sequences of c) and d) and at the end
f) 1 end stay.

Additionally, the intermediate trusses of the first type can be partially replaced by intermediate trusses of the third type. In this case, alternating intermediate trusses of the first and third type can be used.

A solar installation according to the invention has a plurality of solar panels, which are arranged so as to be able to pivot about 2 axes between two supporting cables one behind the other and mounted on a beam. The beam, typically 60 cm-300 cm wide and 100 cm-1500 cm long, is described in the further embodiments as the panel. If the panel is tracked to the sun, it is rotatably mounted on the supporting cables and equipped with a lever, which permits coupling with a tracking cable. The distance between the panels depends on the direction to the sky in which the supporting cables run, on the location and on the desired maximally permissible shading of the panels in the case of flat solar radiation. Typical distances are in the region of 1.5 to 4 times the panel width.

The supporting cables are pre-tensioned at the end stay. To take up the pre-tension forces the end stay has an anchorage, which can be optimally formed by ground anchors, micro-stakes, earth screws or a concrete fundament or anchorage in rock. Between the row of solar panels and the anchor points, an intermediate fundament is located in each case. If the solar panels can be inclined about a pivotable axis, in the case of the intermediate fundament supports, a beam is arranged as a spacer, so that pivoting is possible. As a result, the pivoting angle can be defined both dependent on the position of the sun and not dependent on the position of the sun (for example in the case of heavy wind conditions). The two supporting cables held apart from one another by the spacer assume the position, which is pre-determined by the angular position of the spacer. Thus, all panels of a row are also pivoted into this angular position. This angular position depends on the drive motor of the pivoting device. This can be controlled by a sun position sensor, but also by wind or load sensors.

Expediently, the pivoting device is realized by a spacer (or beam) arranged in a pivotable manner, which is pivotably arranged on the end stays and the intermediate trusses of the first and second type, and an adjustment device, which engages on the spacer. This is a simple but efficient structure. In this case, the adjustment device for determining the pivoting angle can be supported on the spacer and the support or on the ground and can be variable in length, so that the pivoting angle can be adjusted. A plurality of length-variable adjustment devices can be provided, which may be operated in unison or independently. In one expedient embodiment, the length-variable adjustment devices are release supports, which are coupled with one another by means of a tracking cable. The tracking cable can be adjusted by a drive motor. In this case, at least one drive motor can be provided for the tracking cable for example at the one end of the installation and at least one counteracting force can be provided for tensioning the cables for example at the other end of the installation by a second drive motor, a weight or a spring for example.

An advantageous embodiment proposes that the panels in each case are mounted on the supporting cables, so as to be able to pivot about a tilting axis, which runs perpendicularly to the supporting cable direction, and a tilting device is provided in order to tilt the panels in unison about their tilting axes. For this purpose, a lever arm can be arranged on the panels in an angularly rigid manner. A tracking cable can connect the lever arms, so that the panels can be tilted by means of the lever arms about the tilting axis. For adjusting the tracking cable, one or more drive units can be provided. An expedient embodiment proposes that at least one drive motor for the tracking cable is provided for example at the one end of the installation and at least one counteracting force is provided for tensioning the cables for example at the other end of the installation by a second drive motor, a weight or a spring for example. In the case of heavy wind conditions, the tilting device brings the panels to a flat angle (0-15°), advantageously (5-12°), in order to reduce wind load on the installation.

Advantageously, the pivoting device is supported on the spacer and the support and formed so as to be length-variable, in order that the pivoting angle can be adjusted by varying the length of the pivoting device.

Even though only one spacer can be adjusted on a support, it is nevertheless desirable if a plurality of spacers is mounted on supports, so as to be able to pivot about a pivotable axis. Advantageously, a plurality of length-variable pivoting devices is also provided. Expediently, means are also provided in order to vary their length at the same time and to the same extent.

An economic embodiment of such length-variable pivoting devices is release supports, the angle of which can be determined by means of a tracking cable or a rod connection between the release supports.

A row of solar panels can be tensioned without intermediate support between the anchor points. However, the length of such an installation is limited by the wind load and the risk of the solar panels oscillating due to influence of the wind. Therefore, it is desirable that at least one intermediate truss, which engages on both supporting cables and stabilizes their position, is provided for the supporting cables. Such intermediate trusses can have a supporting or staying function. The supporting cables change direction across the support. In the case of supporting intermediate trusses, this angle is convex to the sky, in the case of staying intermediate trusses, concave to the sky.

In order to form a supporting intermediate truss, a spacer is advantageously arranged on a support in a pivotable manner. In order to form a staying intermediate truss, a support anchored in the ground by tension, on which a spacer is mounted in a pivotable manner, can be used. In addition, only one or more tensioned guy-wires tethered to a solid substrate can be provided, which engage on the pivot point of a spacer.

In order to prevent oscillation from building up on a solar installation extending over a plurality of sections, provision can be made for one or more intermediate trusses to subdivide the row of the solar panels into unequally long sections. This has the advantage that each section has its own natural frequency, so that neighbouring sections oscillate at different frequencies and therefore mutually dampen one another. Such intermediate trusses can thereby be of a different nature. By virtue of these intermediate trusses, the basic tension in the supporting cable can be reduced.

The panels can be arranged at a rigid angle between the supporting cables. Advantageously, however, not only the pivoting position of the spacers can be adjusted, but also the tilting position of the panels relative to the direction of the supporting cables. For this purpose, the panels in each case are mounted on the supporting cables, in each case so as to be able to pivot about an individual tilting axis. In addition, a tilting device extending over the length of the row is provided, in order to tilt the panels in unison about their tilting axes. The alignment of each individual panel can be adjusted in advance. By operating the tilting device, all panels are pivoted in unison and remain parallel to each other, even though they are arranged thereon at different angles to the supporting cable.

Advantageously, further cables can be arranged on the intermediate trusses and end stays below the solar panels, in order to attach rigid or flexible shading elements or protection elements for protecting against rain or wind. This can be done, for example, if a parking area, for example, is to be shaded or protected against rain by the solar installation.

In order to achieve even greater energy yield per solar panel surface area, in each case reflector elements, such as mirrors, can be provided between the solar panels on the supporting cables, the pivoting angle of which can be adjusted independently of the solar panels about an axis of rotation running perpendicularly to the supporting cable direction. The solar radiation striking the reflector elements can be reflected onto a neighbouring solar panel (photovoltaic module). In this way, the light intensity striking the photovoltaic cell can be substantially increased.

It is conceivable to mechanically couple together a plurality of rows of solar installations arranged next to each other. This has the advantage that the intermediate trusses do not require any separate stays in order to take up the forces transverse to the cable direction and further costs can be reduced. As a result, the stability of the solar installation is also further improved.

In the event of heavy wind conditions, on the one hand, the tilting angles of the panels can be adjusted through the possibilities for adjustment and, on the other hand, the pivoting angles of the spacers can be varied, so that the resultant load on the installation is minimized. In the event of snow, the panels can be steeply inclined and additionally a steep pivoting angle can be set, so that snow cover is minimal and the snow can easily slide off. Thus, the weight of the snow on the panels is limited and additionally the solar panels are immediately functional again after the snowfall.

A structure, with which such tilting of the panels can be achieved is known per se from U.S. Pat. No. 4,832,001. On the panels, a lever arm is arranged in an angularly rigid manner and a tracking cable is connected to the lever arms. By means of the tracking cable, the lever arms can be tilted about the tilting axis. The drive motor of such a tracking cable is described further below in connection with the description of the figures.

The wind-induced forces on the supports can also be reduced by the fact that the installation is prevented from oscillating at a natural frequency. In the case of a solar installation with a plurality of solar panels, wherein at least one anchor point is respectively provided in front of and after the row of solar panels, suspended in a row on the supporting cables, in which anchor points the supporting cable(s) are directly or indirectly anchored, at least one intermediate truss, which is arranged between two solar panels of the solar panel row, is provided for the supporting cables. A reduction in wind load to be considered maximum is achieved with this installation by virtue of the fact that one or more intermediate trusses subdivide the row of solar panels into unequal sections.

In the case of such a solar installation with solar panels suspended on two supporting cables and at least one intermediate truss, irrespective of whether this intermediate truss subdivides the row of solar panels into equal or unequal sections, it is an advantage basic to the invention if at least one of the intermediate trusses is formed so as to stay the supporting cables.

Expediently, the solar panels of such an installation are suspended between two supporting cables. With such a two-cable suspension, at least between the row of solar panels and the anchor points a spacer is respectively provided, which maintains the supporting cables in the region of the row of solar panels at a predetermined distance in relation to each other. Also, at least one of said intermediate trusses advantageously engages on both supporting cables.

In accordance with still another embodiment, the end supports are realized by two pillars arranged one behind the other in the cable direction. The funicular forces are dissipated with the first pillar. The second pillar, equipped with a spacer and a pivoting device, determines the cable distance for the panels and the pivoting angle of the supporting cables. This has the advantage that the bearing of the pillar with spacer does not need to take up the pre-tensioning force of the cables.

Advantageously, a control, which measures the wind load and/or weight load acting on the solar panels, is provided and when a certain limit value is exceeded, changes the tilting and/or pivoting position of the solar panels, so that the wind load and/or weight load is reduced. The amount of the wind load and/or weight load can, for example, be measured by the tensile load, that is to say, its change, acting on the second cable.

In accordance with a further independent aspect of the invention, the row of solar panels is subdivided into sections (A, C) by the at least one intermediate truss. The subdivision of the span of the solar installation by intermediate trusses into unequally long sections has the advantage that the risk of oscillations building up on the supporting cables is reduced.

### BRIEF DESCRIPTION OF THE DRAWINGS

The invention is described in more detail below with reference to the figures:

FIG. 1 shows a solar installation according to the invention with a row of 9 solar panels.

FIG. 2 shows a solar installation according to the invention with a row of 16 solar panels.

FIG. 3 shows a front view of the installation in accordance with FIG. 1 or 2.

FIG. 4 shows a cross-section through the installation in accordance with FIG. 1 or 2.

FIG. 5 shows the installation according to FIG. 1 in a side view.

FIG. 6 shows the installation according to FIG. 6 in a top view.

FIG. 7 shows a perspective sketch of a first intermediate truss.

FIG. 8 shows a perspective sketch of a second intermediate truss.

FIG. 9 shows a perspective sketch of a third intermediate truss.

FIG. 10 shows a schematic sketch of the angle adjustment of the panels.

FIG. 11 shows a graphic to illustrate the control of the angle adjustment in the event of wind.

FIG. 12 shows schematically the support structure of a solar installation according to the invention with various supports, but without solar panels.

FIG. 13 shows a solar installation tracked on one axis, realized on the basis of this concept with a device for tilting the solar panels.

FIG. 14 shows a detail of the solar installation in accordance with FIG. 13.

### DETAILED DESCRIPTION OF THE ILLUSTRATED EMBODIMENTS

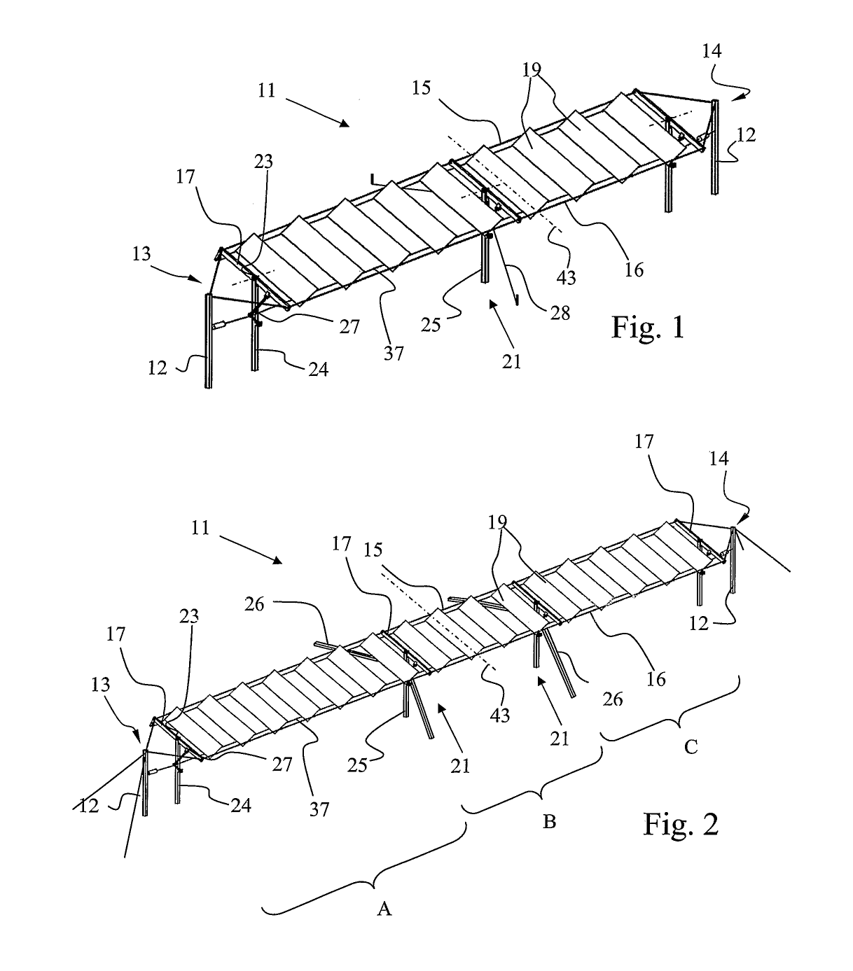

The solar installations 11 illustrated in FIGS. 1-6 are tensioned in each case between two anchor points 13 and 14. Both anchor points 13, 14 are formed by a pillar 12. Two supporting cables 15, 16 are anchored on the top of the pillars 12. These supporting cables 15, 16 are maintained at a determined distance in coordination with the solar panels 19, by a spacer or support 17 arranged at a distance from the anchor point. The spacers 17 are arranged in a pivotable manner on a support 24, 25 about a centrally-arranged pivotable axis 23. Between the two supporting cables 15, 16, a row of solar panels 19 are suspended behind and apart from one another. At a certain distance from the pillars 12, an intermediate truss 21 of a first type is formed between two solar panels 19. The intermediate truss 21 of the first type subdivides the installation into a first section with five and a second section with four solar panels 19. The intermediate truss 21 in this example is formed by a support 25 with a spacer 17 arranged in a pivotable manner thereon. As a result of the intermediate truss, the sag of the supporting cables 15, 16 is limited and the pre-tensioning forces of the supporting cables can be reduced and the end stays can be less massive.

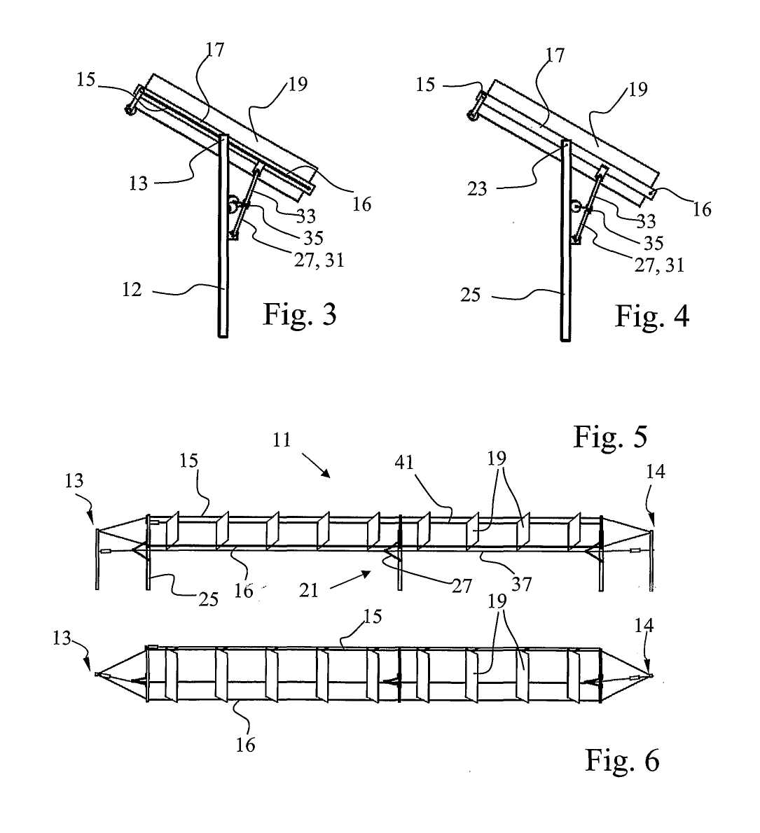

The spacers 17 in each case are mounted in a pivotable manner about the pivotable axis 23. Their pivoting position is determined by a pivoting device 27. The pivoting device 27 is formed by a release support (see FIGS. 3 and 4). The release support has a first and a second lever 31, 33, connected to one another by a toggle link 35. With the first lever 31, the support is hinged on the support 25 at a distance from the pivotable axis 23. The second lever 33 is hinged on the spacer 17 at a distance from the pivotable axis 23.

By buckling the elbow lever in the toggle link 35, the distance between the two hinge points on the spacer 17 and on the support 25 is shortened and therefore the spacer is pivoted. The release position is determined by a first tracking cable 37 (clearly visible in FIG. 5), which is tensioned between the two pillars 12.

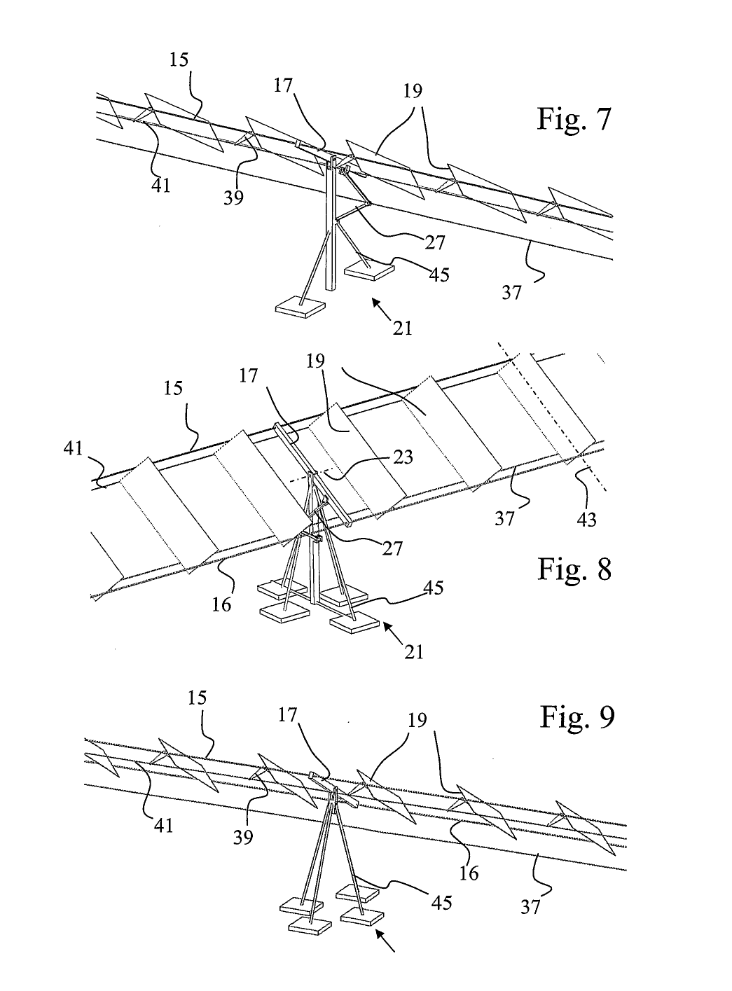

Adjustment of the tilting position of the panels is also provided. Each panel 19 is mounted about a tilting axis 43, which runs through the hinge points of the panels on the supporting cables 15, 16. This tilting axis 43 extends from the first supporting cable 15 to the second supporting cable 16. On one side, the panel 19 is equipped with a lever arm 39 (see FIGS. 7, 9 and 10). This lever arm 39 is connected to the panel 19 in an angularly rigid manner. It is fastened on its outer end to a second tracking cable 41. Its place of attachment on the tracking cable 41 is infinitely variable. As a result, the basic alignment of all panels suspended on the tracking cable 41 can be adjusted. The panels 19 can be tilted by adjusting the tracking cable.

By pivoting the spacers and tilting the panels, the panels can be optimally aligned to the position of the sun. The first and second tracking cables 37 and 41 can be easily controlled by means of a sensor system known to the person skilled in the art.

By irregularly subdividing the row of solar panels by the pillars 12 and the intermediate trusses 21, the individual sections A, B, C (FIG. 2) of the solar installation, illustrated by way of example, behave differently during heavy wind conditions. Oscillations, which may occur in a section, cannot build up with oscillations in the neighbouring section, but on the contrary are dampened. This enables the installation also to be used in relatively strong winds.

Different variants of intermediate supports are possible. In FIGS. 1-6 (especially FIG. 4), the intermediate trusses of a first type are formed by T-shape frames, which consist of a support 25, spacer 17 and lateral struts 26 or stays 28. Such intermediate trusses of the first type are characterized in that no or only minimum forces are taken up in the cable direction. Thus, either the intermediate truss is therefore resilient in the cable direction or the cable can be moved relative to the spacer. An option for the resilient structure of the intermediate truss of the first type is to form this as a pendulum support. Such a pendulum support can be constructed with two legs and at the base or within the pillar region can have a hinge which permits a tilting movement in the supporting cable direction. A relative movement between cable and spacer can be realized, if the cable lies on the spacer or is fed through an eyelet.

Intermediate trusses of a second type can also be used in place of a stayed support 25. Such intermediate trusses of a second type are supports supported or stayed on all sides, which can take up both tensile as well as compressive forces in the supporting cable direction (FIG. 8). The stays of the intermediate trusses of the second type can be realized by supports or wire guys. FIGS. 7-9 illustrate exemplary embodiments of intermediate trusses. The decision which type or which combination of different intermediate supports is to be selected, depends on the specific design of the installation, for example the maximum admissible sag of the supporting cables between the supports, the weight and surface area of the panels and also on the local position, ground and wind conditions.

FIG. 7 illustrates an intermediate truss of the first type stabilized crosswise to the supporting cable direction and capable of taking up tensile forces. It is equipped with an adjustment device 27, as already described above. FIG. 8 illustrates an intermediate truss of the second type stabilized lengthwise and crosswise to the supporting cable direction and capable of taking up tensile forces. This also has a release support. The support 25 is only necessary, in order to hinge the release support thereon. If such a release support is omitted, the intermediate truss can be realized only by pillars or cables capable of taking up tensile forces. FIG. 9 illustrates such an intermediate truss of a third type capable of taking up tensile forces, wherein the support 25 is missing. An intermediate truss of a fourth type consists of only a guy-wire. Such guy-wires can engage on the centre of the spacers or supporting cables and are advantageously used if large distances have to be overcome between the point of engagement on the spacer and possible anchor points.

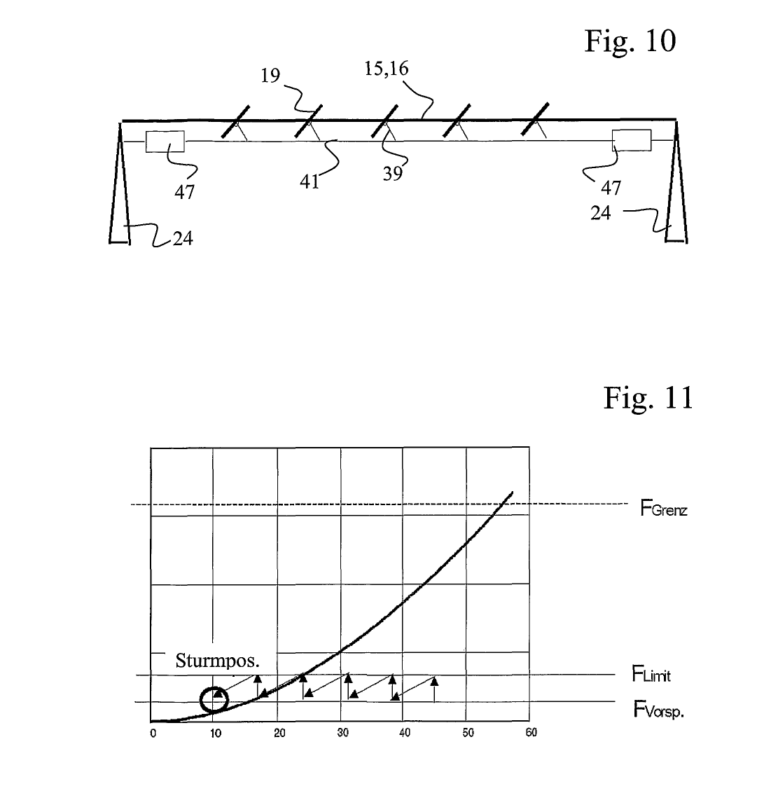

FIG. 10 schematically shows the tilting angle control. Attached to the lever arms 39 is a tension member, for example a tracking cable, connecting the lever arms 39. This tension member 41 is fastened on both ends. As is evident from FIGS. 1, 2, 5 and 6, the tension member is fastened to the terminal spacers 17. A servomotor 47 is provided at both ends of the tension member. These servomotors run synchronously and in the opposite direction. If one motor releases cable, the other motor winds in cable. Therefore, the tension member can be adjusted in the tensioned state. The solar panels are tilted at an angle to the supporting cable direction by such an adjustment of the tension member. Each motor 47 is connected to a tension sensor. If the tension sensor of one motor 47 is more heavily loaded than the tension sensor of the other motor, wind load or snow load is present. In the case of an asymmetrical load, this can be changed by a control, programmed accordingly, of the tilting angles so that the load is reduced. In the case of snow load, the panels are aligned vertically or almost vertically. In the case of wind load, they are laid flat for example as far as 10° to the horizontal.

FIG. 11 illustrates loading under heavy wind dependent on the tilting angle of the panels. On the x-axis, the tilting angles are illustrated from 0-60 ° to the horizontal. On the y-axis, the force arising at a given wind speed. The curve of the wind load rises with increasing tilting angle. In order to prevent strong wind loading a limit is preset in the control software. The lower limit F_{vorsp.} is the tensile force of the pre-tensioning of the tension member. F_{Limit} designates the highest permissible measured wind load. F_{Grenz} designates the highest permissible load on the installation. Far below the limit value F_{Grenz}, when the F_{Limit} value is reached, the tilting angle of the panels is reduced until the pre-tensioning value is obtained. At an angle of 10°, the tilting angle is no longer reduced.

The pivot movement for pivoting the entire row of panels about the pivotable axis 23 is formed in the same way as the mechanism for tilting the panels. The tension member 37, running parallel to the supporting cable direction, engages on the release supports 27. The terminally-positioned servomotors 47 move the tension member back and forth, in order to change the pivoting angle.

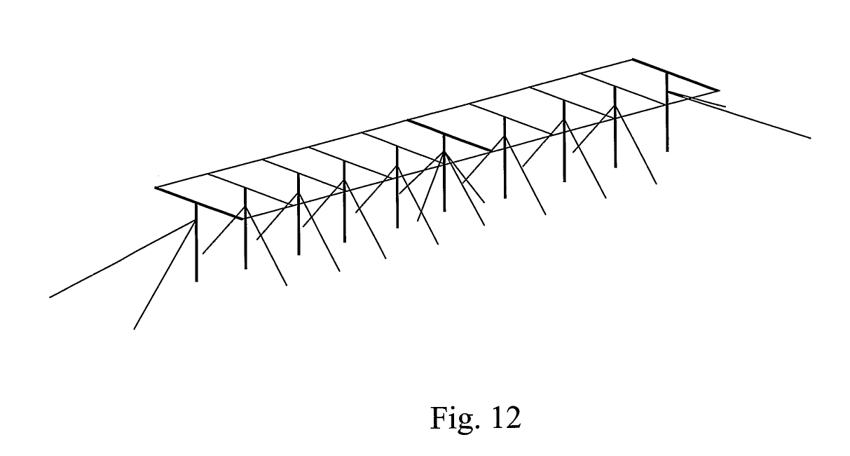

FIG. 12 schematically shows a solar installation according to the invention comprising pillars at the beginning and at the end with end stays, a plurality of intermediate trusses of a first type and an intermediate truss of a second type in the centre of the installation.

An exemplary embodiment of the solar installation is equipped with a device for tilting the solar panels and has a plurality of intermediate supports of the first type without any device for pivoting the supporting cables. Such an installation is located in the east-west direction on a slope. This permits the alignment of the panels to be tracked to the position of the sun over the course of the day.

Exemplary Embodiment:

A solar installation with end stays 1000 m apart is configured, for example, as follows:
1 end stay
6 intermediate trusses of the first type in each case spaced 50 m apart
1 intermediate truss of the second type 50 m apart from the last intermediate truss of the first type
6 intermediate trusses of the first type in each case spaced 50 m apart
1 intermediate truss of the second type in each case spaced 50 m apart
5 intermediate trusses of the first type in each case spaced 50 m apart
1 end stay.

The solar panels have a support width of 8.5 m and are configured with solar panels of a width of 1.6 m and arranged 4 m apart on the supporting cables.

1. A solar installation, comprising:
a plurality of solar panels, suspended in a row between two supporting cables arranged at a distance from each other,
at least two end stays for substantially tensioning the two supporting cables, and
one or more intermediate trusses to support the two supporting cables, the one or more intermediate trusses including one or more trusses of a first type formed by one of pillars with side struts, pillars with guy-wires or a pendulum support, the one or more trusses of a first type being inserted so that they can take up forces at right-angles to the two supporting cables and so that the distance between the at least two end stays and two intermediate trusses of the one or more intermediate trusses is selected so that the cable sag is between about 0.5% and 6%, of the respective distance between the at least two end stays and between two intermediate trusses of the one or more intermediate trusses.

2. The solar installation according to claim 1, the distance between the end stays and the two intermediate trusses is between approximately 15 m and 150 m.

3. The solar installation according to claim 1, wherein an intermediate truss of a second type is stayed or supported, in such a manner that forces can be taken up in a direction of the two supporting cables and at right angles thereto.

4. The solar installation according to claim 3, further comprising an intermediate truss of the second type is inserted per every 3-20 intermediate trusses of the first type or per every 4-12 intermediate trusses of the first type.

5. The solar installation according to claim 3 the row of the plurality of solar panels is at least partially subdivided into unequally long sections by the one or more intermediate trusses of at least one of the first and second type.

6. The solar installation according to claim 1 wherein the at least one intermediate truss of the first type can be pivoted about a pivotable axis, running substantially perpendicularly to the supporting cables.

7. The solar installation according to claim 1 further comprising a spacer mounted in a pivotable manner on the one or more intermediate trusses, on which the two supporting cables are arranged.

8. The solar installation according to claim 3, further comprising end stays and intermediate trusses of a first and second type.

9. The solar installation according to claim 7, further comprising one or more intermediate trusses through guy-wires between supporting cables or the spacer and the ground to stabilize the position of the supporting cables.

10. The solar installation according to claim 1, further comprising at least two end stays and a plurality of intermediate trusses of a first, second and third type.

11. The solar installation according to claim 1, further comprising an adjustment device for adjusting a determined pivoting angle of the plurality of solar panels about a pivotable axis running in a direction of at least one of the two supporting cables.

12. The solar installation according to claim 11, further comprising a spacer arranged in a pivotable manner on the at least two end stays and on the one or more intermediate trusses of the first and a second type, the adjustment device engaging the spacer.

13. The solar installation according to claim 12, wherein the adjustment device for determining a pivoting angle is supported on the spacer and on a support or on the ground and is variable in length, so that the pivoting angle can be adjusted.

14. The solar installation according to claim 13 further comprising a plurality of adjustment devices with means for varying lengths of the plurality of adjustment devices at a same time.

15. The solar installation according to claim 14, wherein the plurality of adjustment devices are release supports to one another by a tracking cable.

16. The solar installation according to claim 15, further comprising at least one drive motor for operating the tracking cable.

17. The solar installation according to claim 16, wherein the at least one drive motor is provided a first end of an installation and further comprising at least one counteracting force for tensioning the two supporting cables at a second end of the installation by at least one of a second drive motor, a weight or a spring.

18. The solar installation according to claim 1, wherein the panels are each mounted in a pivotable manner on the supporting cables about a tilting axis which that runs perpendicularly to a direction of the supporting two supporting cables, and further comprising a tilting device for tilting the panels in unison about a respective tilting axis axes.

19. The solar installation according to claim 18, further comprising a plurality of lever arms each arranged on the panels in an angularly rigid manner and a tracking cable connected to the lever arms for tilting the plurality of lever arms about the respective tilting axis.

20. The solar installation according to claim 19, further comprising one or more drive units for adjusting the tracking cable.

21. The solar installation according to claim 20, further comprising at least one drive motor for the tracking cable a first end of an installation and at least one counteracting force comprising at least one of a second drive motor, a weight and a spring for tensioning the two supporting cables a second end of the installation.

22. The solar installation according to claim 1 the two supporting cables are arranged below the plurality of solar panels on the one or more intermediate trusses and at least two end stays for attaching a plurality of rigid or flexible shading elements or a plurality of elements for protection against rain.

23. The solar installation according to any one of claim 1, further comprising a plurality of reflector elements on the two supporting cables between the plurality of solar panels, each of the plurality of reflector elements having a pivoting angle about a rotational axis running perpendicularly to a direction of the respective supporting cable that can be adjusted independently of the plurality of solar panels.

24. The solar installation according to claim 1, further comprising a plurality of rows of solar installations, arranged next to each other and mechanically coupled with one another.

25. The solar installation according to claim 1, wherein under heavy wind conditions, an angle of inclination of each of the plurality of solar panels can be adjusted, so that the resultant load on the installation is minimized.

26. The solar installation according to claim 1, wherein in the event of snow the plurality of solar panels can be steeply inclined, so that snow cover is minimal and the snow can easily slide off of the plurality of solar panels.

27. The solar installation according to claim 1, further comprising a control that measures a wind load and/or weight load acting on the plurality of solar panels, and if a certain limit value is exceeded the tilting and/or pivoting position of the solar panels is changed in such a way that the wind load and/or weight load is reduced.

28. The solar installation according to claim 1, wherein the end stays are comprised of two pillars, arranged one behind the other in a direction of the two cables.

29. A solar installation, comprising:
a plurality of solar panels suspended in a row on two supporting cables arranged at a distance from each other;
at least two end stays for tensioning the two supporting cables; and
one or more intermediate trusses for supporting the two supporting cables, the row of the plurality of solar panels being subdivided into sections by one or more intermediate trusses.
